(19) United States
(12) Patent Application Publication
(10) Pub. No.: US 2009/0202720 A1
(43) Pub. Date: Aug. 13, 2009

(54) Film Forming and Cleaning Method

(76) Inventor: Kotaro Miyatani, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/922,110

(22) PCT Filed: Jun. 15, 2006
(86) PCT No.: PCT/JP2006/312034

§ 371 Date: Apr. 13, 2009

(30) Foreign Application Priority Data
Jun. 15, 2005 (JP) 2005-175796

(51) Int. Cl. C23C 16/52; C23C 16/44

(52) U.S. Cl. 427/248.1; 118/719

(57) ABSTRACT

A film forming and cleaning method according to the present invention comprises a temperature adjusting step performed between a film forming step and a cleaning step. In the film forming step, a process gas is supplied into a process vessel (1) to form a film on a substrate (W) in the process vessel (1), while a first part (4) inside the process vessel (1) is heated to a first temperature (for instance, 200 degrees Celsius) and a second part (side wall) inside the process vessel (1) is also heated to a second temperature (for instance, 90 degrees Celsius) lower than the first temperature. In the temperature adjusting step, the temperature of the first part (4) is lowered to a level closer to the second temperature. In the cleaning step, a cleaning gas is supplied into the process vessel (1) to remove deposits deposited on the surfaces of the first part and the second part.

### TECHNICAL FIELD

The present invention relates to a film forming and cleaning method to subject a substrate to a film forming process in a process vessel and then remove deposits in the process vessel. The present invention also relates to a film forming apparatus and a program storage medium used in the method.

### BACKGROUND ART

A semiconductor device is subjected to a film forming process during the manufacturing process. The film forming process is generally performed by changing a process gas into plasma or thermally decomposing a process gas in a vacuum atmosphere to activate the process gas and also by having active species or reaction products deposited on a surface of the substrate. In the film forming process, when a thin film is formed on a surface of a substrate, the reaction products are deposited also on surfaces of inner members and on an inner side face of the process vessel. Therefore, when a thickness of the deposits surpasses a reference value, cleaning is performed by feeding a cleaning gas into the process vessel (Refer to for instance, JP11-330063A (paragraph 0019 and paragraph 0020).

A plasma film forming apparatus employed for executing the process as described above is briefly described below with reference to FIG. 11. As shown in FIG. 11, a supporting table 11 for supporting a substrate D thereon is provided in a vacuum vessel 10, and a gas supply member 12 is provided above the supporting table 11. The gas supply member 12 is provided on a cylindrical member referred to as inner wall 13. The gas supply member 12 is configured to supply a shower-like gas to the substrate D and flow a gas from an upper side to a lower side thereof. A transmissive window 14 and a flat antenna 15 for microwave radiation are provided above the gas supply member 12. The film forming apparatus as described above is suited to the use for forming, for instance, a CF film (a fluorine-added carbon film) on a substrate D. The inner wall 13 is heated by a heater 16 to 200 degrees Celsius during the film forming process. It is empirically known that the in-plane (intra-surface) uniformity of the thickness of the CF film formed on the substrate D is improved by heating the substrate D to about 380 degrees Celsius and the inner wall 13 to about 200 degrees Celsius.

On the other hand, a side wall of the vacuum vessel 10 is heated by a heater 17 to, for instance, 90 degrees Celsius. It is desirable, from the viewpoints of the thickness of the CF film on the substrate D and the in-plane uniformity thereof, that the side wall of the vacuum vessel 10, which is located slightly away from the process atmosphere, is also heated. On the other hand, a limit for the temperature is about 90 degrees Celsius for the safety of an operator.

The film forming process to the substrate D is repeated, and when the thickness of deposits in the vacuum vessel 10 surpasses a reference value, cleaning process is performed. In the cleaning process, temperatures at each part inside the vacuum vessel 10 are kept at the same levels as those during the film forming process, and an O₂ (oxygen) gas as a cleaning gas is supplied into the vacuum vessel 10. Then microwaves are radiated to the O₂ gas to generate plasma, and the CF film which is deposited on the inner wall of the vacuum vessel 10 is ashed and removed by this plasma (Refer to, for instance, JP2004-296512A (paragraph 0033, FIG. 4)).

In this process, deposits (CF film) deposited on the high temperature part (inner wall 13) heated to as high as 200 degrees Celsius and those (CF film) deposited on the relatively low temperature part (the side wall of the vacuum vessel 10) heated to about 90 degrees are cleaned at the same time. Then, decomposition products of the deposits deposited on the high temperature part are transferred onto the side wall of the vacuum vessel 10 which is the low temperature part. Therefore, a quantity of deposits at the low temperature part temporally increases while cleaning of the deposits at the high temperature part is performed. After all the deposits at the high temperature part are removed, the increased deposits deposited on the low temperature part are removed. Under the circumstances, a long period of time is required for cleaning, which adversely lowers the throughput.

### DISCLOSURE OF THE INVENTION

The present invention has been made in the light of the circumstances as described above, and an object of the present invention is to provide a technique enabling a quick operation for cleaning deposits inside a vacuum vessel after a film is formed in the state where a high temperature part and a low temperature part concurrently exist in the vacuum vessel.

To achieve the object described above, the present invention provides a film forming and cleaning method comprising:

a film forming step of forming a film on a substrate in a process vessel by supplying a process gas into the process vessel while heating a first part in the process vessel to a first temperature and heating a second part in the process vessel to a second temperature lower than the first temperature;

a temperature adjusting step of, after the film forming step, lowering the temperature of the first part to a level closer to the second temperature; and

a cleaning step of, after the temperature adjusting step, supplying a cleaning gas into the process vessel to remove deposits deposited on surfaces of the first part and the second part.

For instance, the first part is an internal member provided in the process vessel, and the second part is a side wall of the process vessel.

For instance, the side wall of the process vessel is cylindrical, and the internal member is a cylindrical one surrounded by the side wall of the process vessel. Alternatively, the process vessel is provided with: a supporting table configured to support the substrate; and a gas supply member positioned between the supporting table and an upper section of the process vessel are provided, and the internal member is a cylindrical one extending downwards from the gas supply member.

When viewed from another aspect, the present invention provides a film forming apparatus comprising:

a process vessel having therein a first part and a second part and configured to accommodate a substrate therein;

a process gas supply system configured to supply a process gas for forming a film on the substrate into the process vessel;

a cleaning gas supply system configured to supply a cleaning gas for removing deposits inside the process vessel into the process vessel;

a first heater configured to heat the first part in the process vessel;

a second heater configured to heat the second part in the process vessel; and

a controller configured to control the process gas supply system, the cleaning gas supply system, and the first and second heaters, the controller being further configured to carry out a control to execute the following steps:

a film forming step of forming a film on a substrate in a process vessel by supplying a process gas into the process vessel while heating a first part in the process vessel to a first temperature and heating a second part in the process vessel to a second temperature lower than the first temperature;

a temperature adjusting step of, after the film forming step, lowering the temperature of the first part to a level closer to the second temperature; and

a cleaning step of, after the temperature adjusting step, supplying a cleaning gas into the process vessel to remove deposits deposited on surfaces of the first part and the second part.

When viewed from still another aspect, the present invention provides a storage medium storing a control program for such a film forming apparatus, the program being configured to have the controller carrying out a control to execute the film forming step, the temperature adjusting step, and the cleaning step.

According to the present invention, the film forming process is carried out in the state where a high temperature part (a first part) and a low temperature part (a second part) are concurrently present in the process vessel; subsequently, temperature adjustment is performed, before the cleaning of the inside of the process vessel, to lower a temperature of the first part to a level closer to a temperature of the lower temperature part (a second temperature). This makes it possible to suppress the phenomenon that decomposition products of deposits deposited on the first part are transferred to the second part in the cleaning step, so that the inside of the process vessel can be cleaned quickly.

### BRIEF DESCRIPTION OF THE DRAWINGS

FIG. 1 is a cross-sectional view schematically showing an embodiment of a film forming apparatus according to the present invention;

FIG. 2 is an exploded perspective view illustrating an area around a process vessel of the film forming apparatus shown in FIG. 1;

FIG. 3 is a bottom view illustrating a gas supply member in the firm forming apparatus shown in FIG. 1;

FIG. 4 is a flow chart illustrating a film forming and cleaning method according to one embodiment of the present invention;

FIG. 5A is a schematic showing the film forming apparatus shown in FIG. 1 and also showing a condition where a firm forming process is being performed;

FIG. 5B is a schematic of the film forming apparatus shown in FIG. 1, showing a condition where a film cleaning process is being performed;

FIG. 6 is a schematic showing conditions where deposits deposited on a first part and a second part in the process vessel are being removed by the conventional method;

FIG. 7 is a graph showing time course changes in thickness of deposits deposited on the second part in the process vessel when the deposits are removed by the conventional method;

FIG. 8 is a schematic illustrating a condition where deposits on the first and second parts in the process vessel are being removed by the method according to the present invention;

FIG. 9 is a graph showing time course changes in thickness of deposits deposited on the second part in the process vessel when the deposits are removed by the method according to the present invention;

FIG. 10 is a table showing results of experiments by an example of the present invention as well as by a comparative example; and

FIG. 11 a cross-sectional view showing a film forming apparatus for illustration of the film forming and cleaning method based on the conventional technology.

### BEST MODE FOR CARRYING OUT THE INVENTION

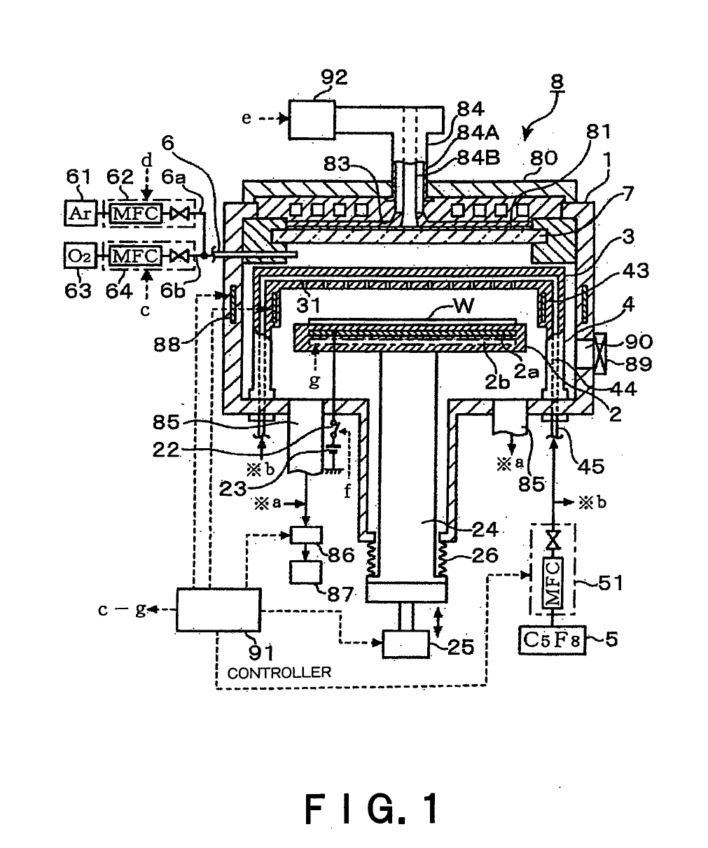

First, a plasma processing apparatus as a film forming apparatus according to one embodiment of the present invention is described below with reference to FIG. 1 to FIG. 3. Reference numeral 1 in FIG. 1 denotes a process vessel made of, for instance, aluminum, which defines a vacuum process chamber. Provided in this process vessel (process chamber) 1 is a disk-shaped supporting table 2 configured to horizontally support a semiconductor wafer W as a substrate, on a surface of which a film is formed. A foil-like electrode 2a is embedded in this supporting table 2, and the electrode 2a is connected to a DC current source 23 via a switch 22. Also embedded in the supporting table 2 is temperature adjusting means 2b for heaters or the like for adjusting temperature of the wafer W. Furthermore provided in the supporting table 2 are a plurality of elevating pins (not shown) for transferral of a wafer W to a transfer means not shown. The supporting table 2 is supported by a supporting column 24 extending up to the bottom of the process vessel 1. The supporting table 2 can be moved up and down by an elevating mechanism 25 via the supporting column 24. A movable portion under the supporting column 24 is covered with a bellows 26 made of stainless steel (SUS).

A disk-shaped gas supply member 3 made of a conductor, e.g. aluminum, is provided above the supporting table 2. This gas supply member 3 has a number of gas supply holes 31 formed on the surface facing the supporting table 2 and is configured as a gas shower head. An inner wall 4, which is a cylindrical member surrounded by the cylindrical side wall of the process vessel 1, is provided in the process vessel 1. The inner wall 4 extends downward from an outer periphery of the gas supply member 3.

In this embodiment, the inner wall 4 corresponds to an internal member as a first part. The side wall of the process vessel 1 corresponds to a second part.

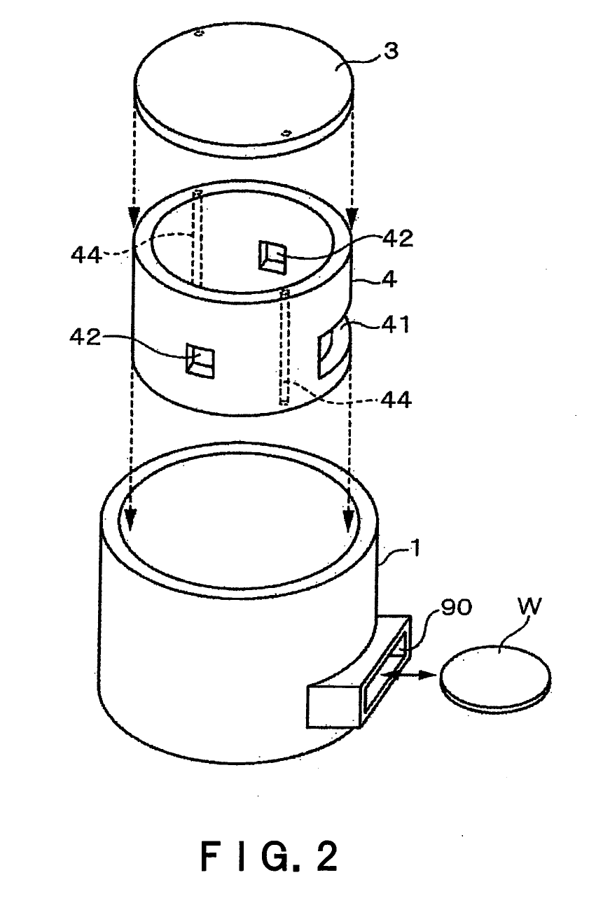

As shown in FIG. 2, a transfer port 41 for a wafer W and windows 42 for observation of the process atmosphere are formed on the inner wall 4. Furthermore, a first heater 43 extending in the circumferential direction is embedded in an upper section of the inner wall 4 as shown in FIG. 1.

Two gas flow paths 44 extending through the inner wall 4 in the axial (vertical) direction are placed diametrally opposite to each other in the circumference of the inner wall 4 (Also refer to FIG. 2). The gas flow paths 44 are used to feed a gas supplied from the outside through a gas supply path 45 to the gas supply member 3. A supply source 5 for a film-forming gas made of a compound containing carbon and fluorine, for instance, a C₅F₈ gas is connected via a gas supply equipment group 51 to the gas supply path 45. The gas supply equipment group 51 includes a valve, a mass flow controller, and the like, and controls gas supply.

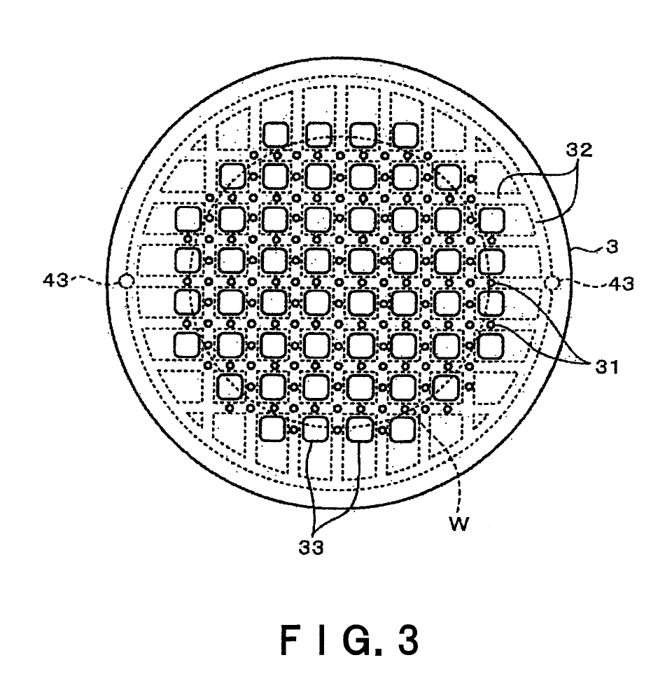

As shown in FIG. 3, a grid-like gas flow path 32 communicated to a number of the gas supply holes 31 are formed inside the gas supply member 3. A number of through-holes 33 each extending in the vertical direction are also formed in the gas supply member 3. The through-holes 33 are provided so that plasma generated in an upper space above the gas supply member 3 can pass therethrough to a lower space.

The gas supply member 3, the flow path 44, the supply path 45, the equipment group 51 and the supply source 5 form a process gas supply system to supply a process gas for forming a film on a substrate W into the process vessel 1.

AS shown in FIG. 1, a gas supply path 6 extending through the process vessel 1 is provided above the gas supply member 3. An upstream side of the gas supply path 6 is branched to two branch pipes 6a and 6b. A gas supply source 61 for an Ar (argon) gas as a plasma gas is connected to the branch pipe 6a via a gas supply equipment group 62, while a gas supply source 63 for an O₂ gas as a cleaning gas is connected to the branch pipe 6b via a gas supply equipment group 64. Each of the gas supply equipment groups 62 and 64 includes a valve, a mass flow controller, and the like and controls supply of the gas.

The supply path 6, the branch pipe 6b, the equipment group 64, and the supply source 63 form a cleaning gas supply system to supply a cleaning gas for cleaning deposits in the process vessel 1 into the process vessel 1.

A dielectric plate (microwave-transmissive window) 7 is provided in an upper section of the process vessel 1. An antenna member 8 is provided directly on the upper surface of the dielectric plate 7. This antenna member 8 has a disk-shaped antenna body 80 and a circular and flat antenna member (slot plate) 81 attached via a lagging (phase-retarding) plate 83 to the bottom surface of the antenna body 80. A number of slot pairs are formed on the flat antenna member (slot plate) 81. The antenna body 80, the flat antenna member 81, and the lagging plate 83 form a radial line slot antenna (RLSA).

Microwaves are supplied to the antenna member 8 via a coaxial wave guide tube 84 from a microwave generator 92. An external wave guide tube 84A of the coaxial wave guide tube 84 is connected to the antenna body 80, and a central conductor 84B of the same is connected via an opening formed on the lagging plate 83 to the flat antenna member 81.

Exhaust pipes 85 are connected to the bottom portions of the process vessel 1. Those exhaust pipes 85 are connected via a pressure adjuster 86 comprising, for instance, a butterfly valve to a vacuum pump 87 which is vacuum exhausting means. A second heater 88 is embedded in the side wall of the process vessel 1. In addition, an inlet/outlet port 90 for a wafer W, which can be opened and closed by a gate valve 89, is provided on the side wall of the process vessel 1 at a position facing the transfer port 41 (FIG. 2) formed on the inner wall 4.

The plasma processing apparatus comprises a controller 91 comprising, for instance, a computer. This controller 91 is configured to control the gas supply equipment groups 51, 62, and 64; the pressure adjuster 86; the first and second heaters 43 and 88, respectively; the temperature adjusting means 2b; the microwave generator 92; the switch 22; the elevating mechanism 25; and other related sections. The controller 91 has a storage medium with a built-in sequence program for executing a series of steps of the after-mentioned film forming and cleaning method to be performed in the process vessel 1, and means for reading out each program command and outputting control signals to various sections.

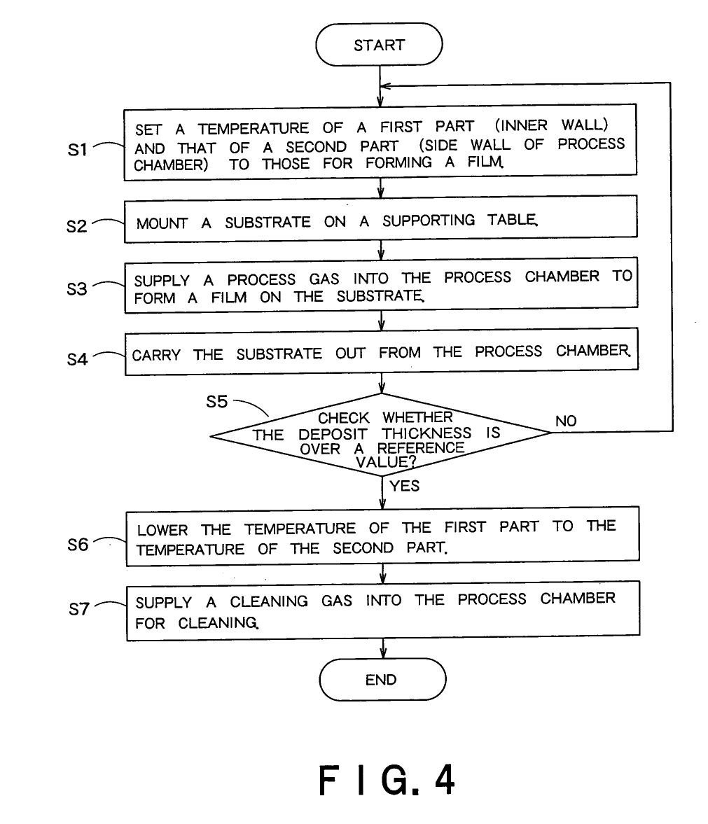

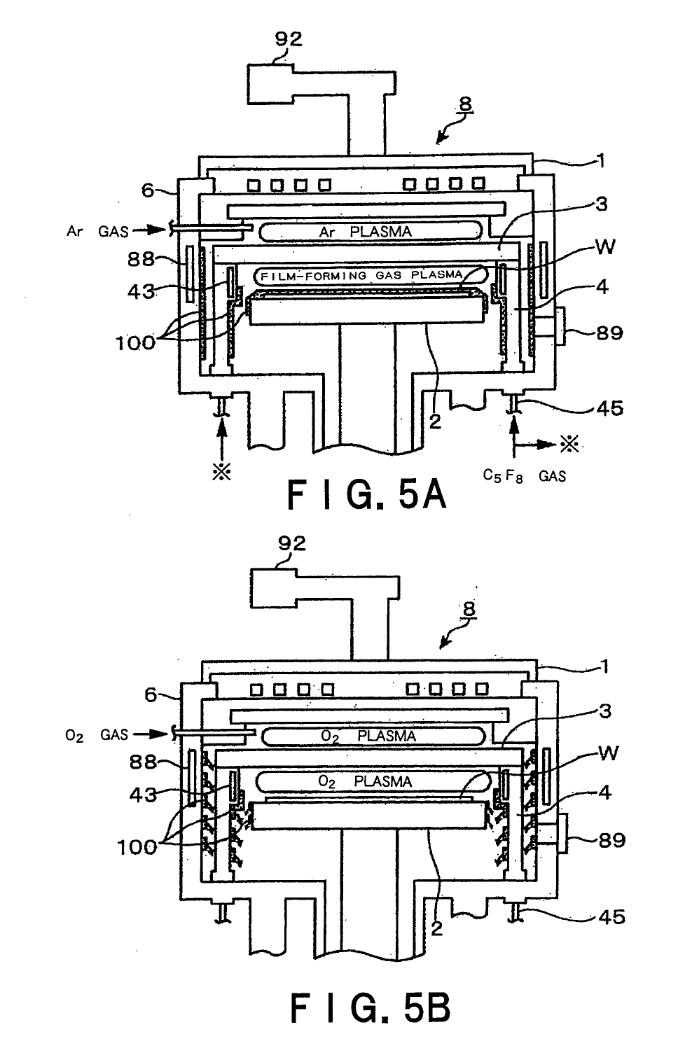

An embodiment of the film forming and cleaning method executed by the plasma processing apparatus as described above is then described below with reference mainly to FIG. 1, FIG. 4, and FIG. 5.

First, the supporting table 2 is heated by the temperature adjusting means 2b to 380 degrees Celsius. Further, the inner wall (first part) 4 is heated by the first heater 43 to 200 degrees Celsius as a first temperature. On the other hand, the side wall (second part) of the process vessel 1 is heated by the second heater 88 to 90 degrees Celsius as a second temperature (step S1 in FIG. 4). Then a wafer W is carried into the process vessel 1 by a transfer arm not shown, and is mounted on and electrostatically attracted to the supporting table 2 (step S2 in FIG. 4).

Then, for instance, a CF film as an inter-layer insulating (dielectric) film is formed on the surface of the wafer W (step S3 in FIG. 4). More specifically, the inside of the process vessel 1 is vacuumed to a predetermined pressure, while supplying an Ar gas from the gas supply path 6 into the process vessel 1 and supplying a C₅F₈ gas as a process gas from the gas supply member 3 of the process gas supply system into the process vessel 1.

On the other hand, a microwave with, for instance, a 2.45 GHz frequency and 2000 W power is supplied from the microwave generator 92. This microwave propagates through the coaxial wave guide 84 in the TM mode, TE mode, or TEM mode and reaches the flat antenna member (slot plate) 81 of the antenna member 8. Then the microwave is propagated via the central conductor 84B in the coaxial wave guide tube 84 and propagated radially from the central portion of the flat antenna member 81 to its peripheral area. During this propagation, the microwave is radiated downward through the dielectric plate 7 from the number of slot pairs on the flat antenna member 81.

As shown in FIG. 5A, the Ar gas in the process vessel 1 is activated by the energy of the microwave, and homogeneous high-density plasma is generated in a space above the gas supply member 3. The active species of Ar flow through the gas supply member 3 and into the processing space under the member 3. The C₅F₈ gas supplied from the gas supply member 3 to the processing space is activated by the active species of Ar flowing therein. Because of this, a CF film 100 is formed on the surface of the wafer W on the supporting table 2. During this process, the CF film 100 is also deposited on the surface of the inner wall 4 as well as on the side surface of the supporting table 2. The active species in the plasma pass through the transfer port 41 and the windows 42 of the inner wall 4 (refer to FIG. 2) and reach the inner side wall of the process vessel 1; therefore, the CF film is also deposited thereon.

In this film-forming process, the wafer W is heated to 380 degrees Celsius by means of the temperature-adjusting action by the temperature adjusting means 2b incorporated in the supporting table 2 and the heat incoming from the plasma. Furthermore, the inner wall 4 surrounding the process atmosphere is heated to 200 degrees Celsius, and the sidewall of the process vessel 1 is heated to 90 degrees Celsius. It has been confirmed through experiments that high in-plane uniformity is obtained for the thickness of the CF film 100 formed on the wafer W under the temperature conditions as described above.

A plasma light-emitting area of the feed gas exists in the inner side of the inner wall 4, but the active species in the plasma also reach the inner side wall of the process vessel 1 as described above. Therefore, the side wall of the process vessel 1 also constitutes part of the environment for the film-forming process. Accordingly, when the side wall of the process vessel 1 is extremely cool, the film-forming process becomes unstable and such factors as the in-plane uniformity of film thickness of the wafer W are deteriorated, so that the side wall (second part) of the process vessel 1 is heated as well. However, when the side wall of the process vessel 1 is heated to an excessively high temperature, there arises a problem with safety of operators. Therefore, although the side wall of the process vessel 1 should preferably be heated to a higher temperature, the side wall is heated to about 90 degrees Celsius from a view point of process efficiency.

When the film-forming process to the wafer W is completed, the wafer W is carried out from the process vessel 1 (step S4 in FIG. 4). Then another wafer W is subsequently carried into the process vessel 1 and is subjected to the same film-forming process as described above. When the thicknesses of deposits deposited inside the process vessel 1 (on the first and second parts) become larger than a reference value (step S5 in FIG. 4), temperature adjustment step is performed (step S6 in FIG. 4), and cleaning step is then performed in the process vessel 1 (step S7 in FIG. 4).

In the temperature adjustment step (step S6 in FIG. 4), a temperature of the inner wall 4 is dropped by reducing a heat value of the first heater 43 from 200 degrees Celsius effected during the film-forming process to 90 degrees Celsius which is at the same level as that of the side wall of the process vessel 1. Then, in the cleaning step (step S7 in FIG. 4), the atmosphere in the process vessel 1 is vacuumed to be discharged, while supplying an O₂ gas as a cleaning gas into the process vessel 1. Then, as shown in FIG. 5B, the O₂ gas is converted into plasma by the energy of the microwave from the microwave generator 92, and deposits (CF film) 100 deposited on the surface of the inner wall (first part) 4 and the side face of the supporting table 2 are removed. On the other hand, active species in the plasma pass through the transfer port 41 and the window 42 (FIG. 2) of the inner wall 4 and reach the inner side wall (second part) of the process vessel 1 as well so as to remove deposits (CF film) 100 deposited thereon. The cleaning in the process vessel 1 is thus completed.

In this embodiment, after the film-forming process is performed to a wafer W, the temperature adjustment is performed to lower a temperature of the inner wall (first part) 4 from the first temperature during the film forming process to a level closer to the second temperature of the side wall (second part) of the process vessel 1, before the inside of the process vessel 1 is cleaned. Then, after the temperature adjustment, cleaning is performed by supplying the O₂ gas as the cleaning gas into the process vessel 1. The above-mentioned operation makes it possible to suppress the phenomenon that decomposition products of the deposits (CF film 100) deposited on the first part are transferred to the second part, which arises when cleaning is performed without the above-mentioned temperature adjustment, and to clean the inside of the process vessel 1 quickly.

The effects provided by the present invention are described below in comparison with those by a conventional technology.

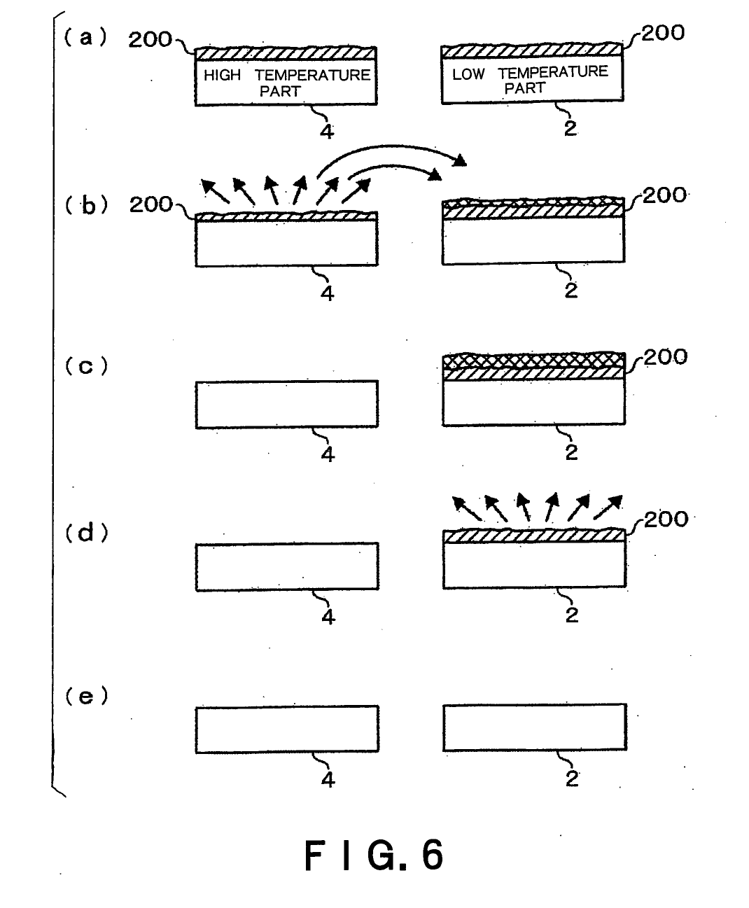

In the cleaning steps based on the conventional technology as shown in FIG. 6, a temperature of the inner wall 4 which is the first part and a temperature of the side wall of the process vessel 1 which is the second part are kept at 200 degrees Celsius and 90 degrees Celsius, respectively, each of which is the same as that during the film forming process. Accordingly, the inner wall 4 as the first part is shown as a high temperature part and the side wall of the process vessel 1 as the second part is shown as a low temperature part.

AS shown in FIG. 6(a) and FIG. 6(b), when an O₂ gas as a cleaning gas is supplied into the process vessel, deposits (CF film) 200 deposited on the high temperature part 4 are first decomposed by the O₂ plasma. The decomposition products are scattered and transferred onto the deposits 200 deposited on the low temperature part 2. It can be considered that decomposition of the deposits occurs also on the low temperature part 2. It is also considered, however, that the decomposition products from the high temperature part 4 are easily trapped on the low temperature part 2. That is, depositing action of the deposits is more dominant than their decomposing action at the low temperature part 2, leading to increased thickness of the deposits. Accordingly, after the deposits 200 deposited on the high temperature part 4 are completely removed as shown in FIG. 6(c), decomposition of the deposits 200 deposited on the low temperature part 2 is accelerated by the O₂ plasma as shown in FIG. 6(d). Thus, the deposits 200 deposited on the low temperature part 2 are completely removed as shown in FIG. 6(e).

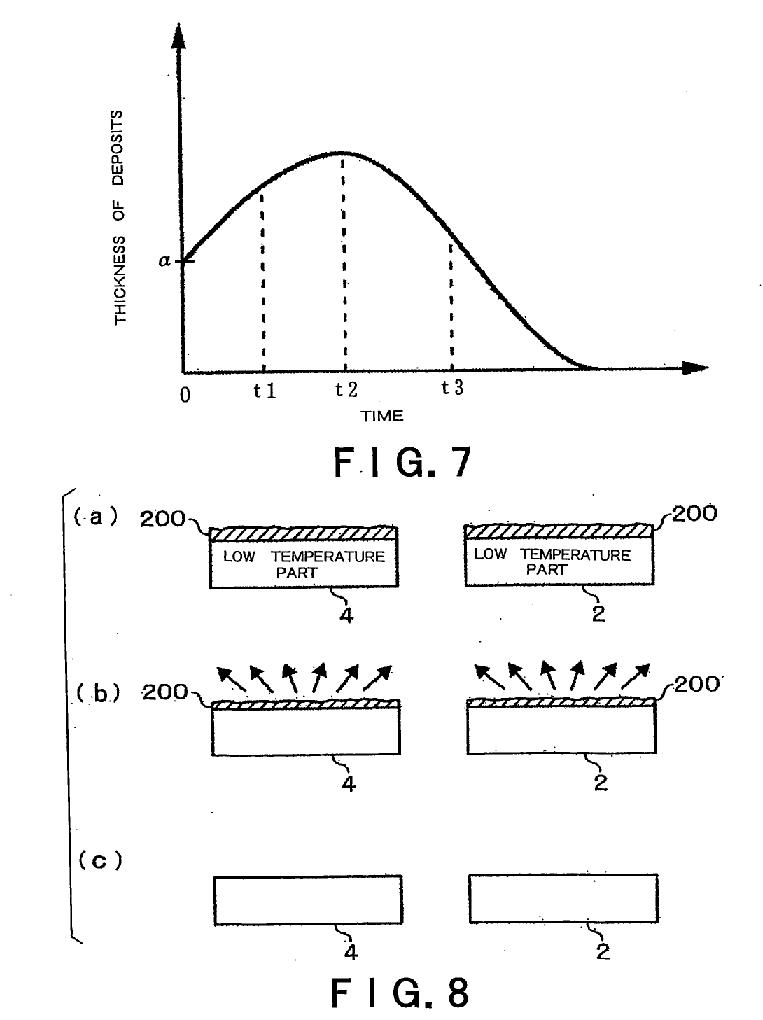

It can be inferred that, in the cleaning process based on the conventional technology, deposits 200 deposited on the high temperature part 4 and deposits 200 deposited on the low temperature part 2 are each removed through the process as described above. FIG. 7 shows time course changes in thickness of the deposits on the low temperature part 2. It can be understood from FIG. 7 that the thickness of the deposits on the low temperature part 2 once becomes larger after the cleaning step is started, and it then becomes smaller as time goes by.

On the other hand, in the cleaning process according to the present invention as shown in FIG. 8, both a temperature of the inner wall 4 which is the first part and a temperature of the side wall of the process vessel 1 which is the second part are set to 90 degrees Celsius through the temperature adjusting process. Therefore, both of the inner wall 4 as the first part and the side wall of the process vessel 1 as the second part are shown as low temperature parts. As shown in FIG. 8(a) and FIG. 8(b), when an O₂ gas as a cleaning gas is supplied into the process vessel, decomposition of the deposits 200 deposited on the first part 4 and of the deposits 200 deposited on the second part 2 is each started by the O₂ plasma almost at the same time. As shown in FIG. 8(c), it can be inferred that the deposits on the two parts 4 and 2 are removed almost concurrently.

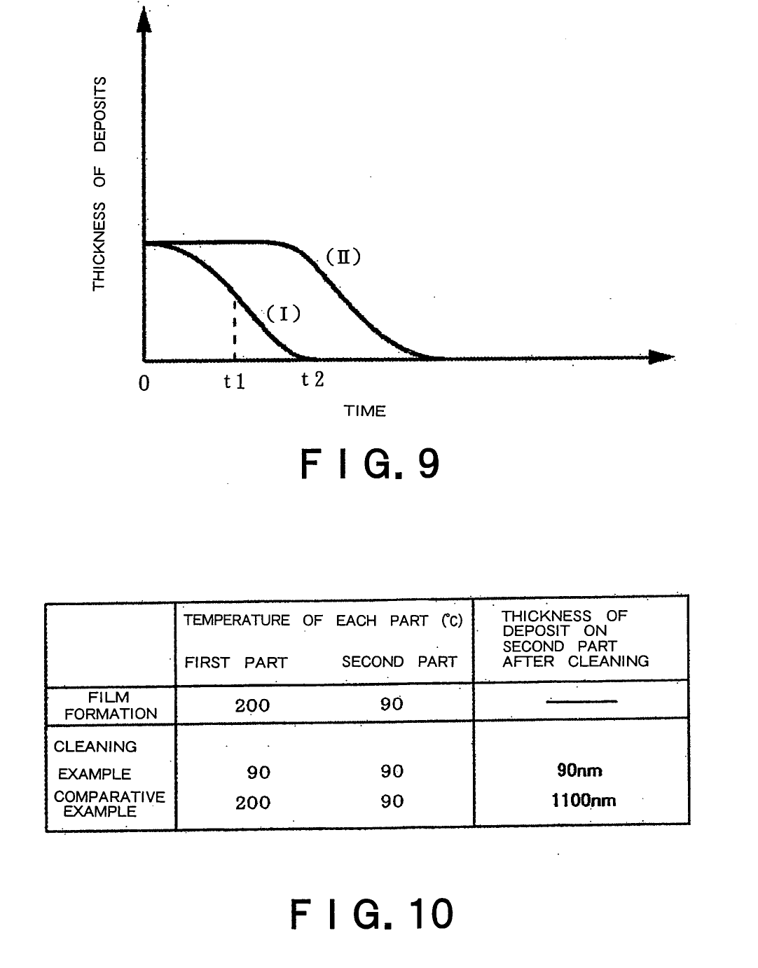

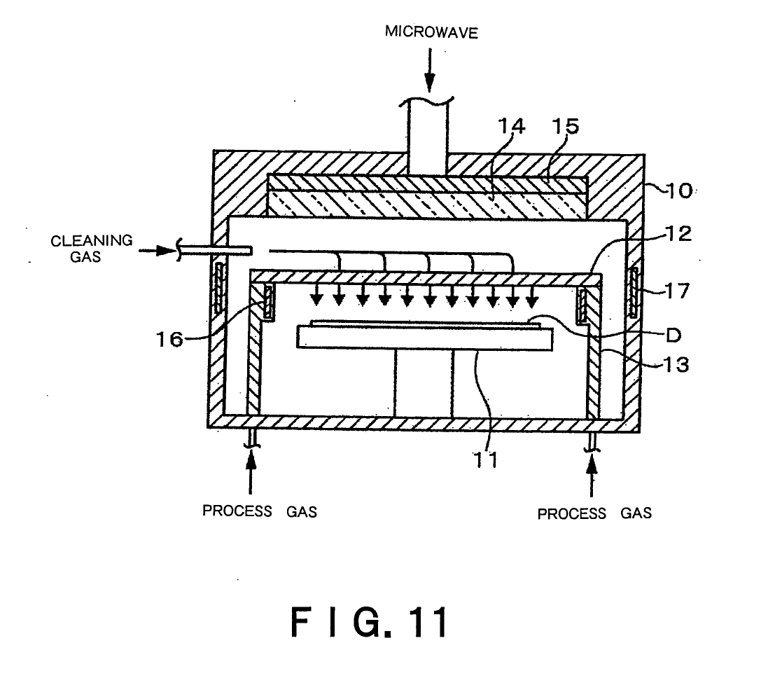

A curve (I) in FIG. 9 shows time course changes of the thickness of deposits on the second part 2. As indicated by the curve (I) in FIG. 9, it can be understood that the thickness of the deposits on the second part becomes smaller as time advances without becoming larger once after the cleaning process is started. This leads to a reduced time period for the cleaning.

The data shown in FIG. 7 is obtained as described below. First, a temperature of the inner wall 4 is set to 200 degrees Celsius, a temperature of the side wall of the process vessel 1 to 90 degrees Celsius, and a temperature of the supporting table 2 to 90 degrees Celsius, respectively. Then three sheets of about-3-cm-square wafer pieces each having a CF film formed thereon with the thickness of α are placed on the supporting table 2, and cleaning with the O₂ plasma is started. The cleaning is once stopped in time t1 (after a first time period t1 from the start of the cleaning process), and one of the wafer pieces is taken out. Then the cleaning is restarted, and a second wafer piece is taken out in time t2 (after a second time period t2 from the start of the cleaning process). Similarly the third wafer piece is taken out from the process vessel 1 in time t3 (after a third time period t3 from the start of the cleaning process). Then each thickness of CF films formed on each wafer piece is measured to obtain the result shown in FIG. 7. In this experiment, because both a temperature of the side wall of the process vessel 1 and a temperature of the supporting table 2 are set to 90 degrees Celsius, it is assumed that changes in a thickness of the CF film on the wafer piece correspond to those in a thickness of deposits on the side wall of the process vessel 1. That is, change in a thickness of deposits on the side wall of the process vessel 1 is estimated based on a result of measurement of a thickness of the film on the wafer piece.

Also, the data indicated by the curve (I) in FIG. 9 is obtained by the same method as that employed in FIG. 7 except that a temperature of the inner wall 4 is set to 90 degrees Celsius.

In the present invention, in the temperature adjustment step executed between the film-forming step and the cleaning step, a temperature of the first part is lowered to a level closer to that of the second part (a second temperature). That is, a temperature of the first part is adjusted not only to the same level as the second temperature, but also to a level lower than the first temperature and higher than the second temperature, and to a level further lower than the second temperature. It is to be noted that a temperature of the first part is preferably adjusted to a level sufficiently close to the second temperature so that a thickness of deposits on the second part becomes smaller with the course of time as shown in FIG. 9, without once becoming larger as shown in FIG. 7.

The data indicated by the curve (II) shown in FIG. 9 is obtained by the same method as that employed in FIG. 7 except that a temperature of the inner wall 4 is set to 150 degrees Celsius. Time required for cleaning in this case is longer than time when the temperature of the inner wall 4 is set to 90 degrees Celsius (as indicated by the curve (I)). In this case, however, the phenomenon that a thickness of the deposits once becomes larger does not occur, and the time required for cleaning is shorter than the time required when the temperature of the inner wall 4 is set to 200 degrees Celsius (as shown in FIG. 7). The present inventor considers, based on the result, that “adjusting a temperature of the first part to a level sufficiently closer to the second temperature” in the temperature adjusting step according to the invention means adjustment of the two temperatures such that a difference between the two temperatures is in about 60 degrees Celsius.

In the description above, it is assumed that the “second part” is the side wall of the process vessel 1, but any part or member in the process vessel may be regarded as a “second part” so long as a temperature of such in the process vessel is lower than that of the first part. Furthermore, any part including a surface of the dielectric plate 7 may be regarded as a “second part” so long as such is exposed to the processing space formed in the process vessel.

Experiments conducted to confirm the effects provided by the present invention are described below.

### EXAMPLE

In the plasma processing apparatus shown in FIG. 1, a temperature to which the inner wall 4 (first part) is heated by the first heater 43 (first temperature) is set to 200 degrees Celsius, and a temperature to which the side wall of the process vessel 1 (second part) is heated by the second heater 88 (second temperature) is set to 90 degrees Celsius. In addition, as an Ar gas and a C₅F₈ gas are supplied into the process vessel 1 to form a CF film on the surface of a wafer W. The thickness of this CF film is 1800 nm. This wafer W is carried out by a transfer arm from inside of the process vessel 1; then, the temperature to which the first part 4 is heated by the first heater 43 is lowered from 200 degrees Celsius to 90 degrees Celsius identical to the second temperature. Then an O₂ gas as a cleaning gas is supplied into the process vessel 1, and the inside of the process vessel 1 is cleaned for 30 minutes.

### Comparative Example

The film formation and cleaning are each performed under the same conditions as those in Example described above except that the temperature to which the inner wall 4 (first part) is heated by the first heater 43 is set to 200 degrees Celsius.

[Result and Analysis]

FIG. 10 shows measurement results of the thicknesses of deposits on the inner side wall (second part) of the process vessel 1 in Example and in Comparative Example after the cleaning step.

As shown in FIG. 10, the measured thickness of deposits is 90 nm in Example of the present invention, while the thickness is 1100 nm in Comparative Example. This result also reveals that cleaning can be completed in a shorter period of time as compared to that required in the conventional technology by carrying out cleaning after a temperature of the first part is lowered from that set for the film-forming step to a level closer to the temperature of the second part in the process vessel as configured by the present invention.

1. A film forming and cleaning method comprising:
a film forming step of forming a film on a substrate in a process vessel by supplying a process gas into the process vessel while heating a first part in the process vessel to a first temperature and heating a second part in the process vessel to a second temperature lower than the first temperature;
a temperature adjusting step of, after the film forming step, lowering the temperature of the first part to a level closer to the second temperature; and
a cleaning step of, after the temperature adjusting step, supplying a cleaning gas into the process vessel to remove deposits deposited on surfaces of the first part and the second part.

2. The method according to claim 1, wherein the first part is an internal member provided inside the process vessel, and the second part is a side wall of the process vessel.

3. The method according to claim 2, wherein the side wall of the process vessel has a cylindrical form, and the internal member is a cylindrical member surrounded by the side wall of the process vessel.

4. The method according to claim 2, the process vessel being provided therein with:
a supporting table configured to support the substrate; and
a gas supply member positioned between the supporting table and an upper part of the process vessel,
wherein the internal member is a cylindrical member extending downwards from the gas supply member.

5. A film forming apparatus comprising:
a process vessel having therein a first part and a second part and configured to accommodate a substrate therein;
a process gas supply system configured to supply a process gas for forming a film on the substrate into the process vessel;
a cleaning gas supply system configured to supply a cleaning gas for removing deposits inside the process vessel into the process vessel;
a first heater configured to heat the first part in the process vessel;
a second heater configured to heat the second part in the process vessel; and
a controller configured to control the process gas supply system, the cleaning gas supply system, and the first and second heaters, the controller being further configured to carry out a control to execute the following steps:
a film forming step of forming a film on a substrate in a process vessel by supplying a process gas into the process vessel while heating a first part in the process vessel to a first temperature and heating a second part in the process vessel to a second temperature lower than the first temperature;
a temperature adjusting step of, after the film forming step, lowering the temperature of the first part to a level closer to the second temperature; and
a cleaning step of, after the temperature adjusting step, supplying a cleaning gas into the process vessel to remove deposits deposited on surfaces of the first part and the second part.

6. A storage medium storing a control program for a film forming apparatus, the film forming apparatus comprising:
a process vessel having therein a first part and a second part and configured to accommodate a substrate therein;
a process gas supply system configured to supply a process gas for forming a film on the substrate into the process vessel;
a cleaning gas supply system configured to supply a cleaning gas for removing deposits inside the process vessel into the process vessel;
a first heater configured to heat the first part in the process vessel;
a second heater configured to heat the second part in the process vessel; and
a controller configured to control the process gas supply system, the cleaning gas supply system, and the first and second heaters,
wherein the storage medium stores therein a program configured to have the controller carrying out a control to execute the following steps:
a film forming step of forming a film on a substrate in a process vessel by supplying a process gas into the process vessel while heating a first part in the process vessel to a first temperature and heating a second part in the process vessel to a second temperature lower than the first temperature;
a temperature adjusting step of, after the film forming step, lowering the temperature of the first part to a level closer to the second temperature; and
a cleaning step of, after the temperature adjusting step, supplying a cleaning gas into the process vessel to remove deposits deposited on surfaces of the first part and the second part.
